(19) United States
(12) Patent Application Publication
(10) Pub. No.: US 2009/0128199 A1
(43) Pub. Date: May 21, 2009

(54) BIASED CLOCK GENERATOR

(75) Inventor: Said E. Abdelli, Minneapolis, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/943,376

(22) Filed: Nov. 20, 2007

(51) Int. Cl. H03L 7/00

(52) U.S. Cl. 327/144

(57) ABSTRACT

A method and system for generating a pair of synchronized clock signals is described. The system includes a first device connected between a first output voltage and an input reference voltage, wherein the first device generates a first output clock signal. Further, the system includes a second device connected in series with the first device. In particular, the second device is connected between the input reference voltage and a second output voltage, wherein the second device generates a second output clock signal. In addition, a first switching circuit is connected in parallel with the first device and a second switching circuit is connected in parallel with the second device. The first switching circuit operates to toggle the first device on and off and the second switching circuit operates to toggle the second device on and off. The first and second switching circuits are coupled to a comparator, which receives a first input clock and a second input clock signal.

### FIELD

The present invention relates generally to a biased clock generator, and more particularly, to a biased clock generator for switched capacitor filters.

### BACKGROUND

Switched capacitor filters (SCFs) are typically used in integrated circuits as they allow for the integration and for the manufacture of various analog and digital components on a single chip. SCFs are based on the realization that a capacitor switched between two circuit nodes at a sufficiently high rate is equivalent to a resistor connecting the two circuit nodes. Since resistors are expensive and are difficult to control, SCF circuits are typically used to simulate resistors.

In a typical SCF circuit, a switch couples a voltage potential to a capacitor. When the switch closes, the voltage potential charges the capacitor. And when the switch opens, the charge remains on the capacitor. Typically, the switch is implemented as a metal oxide semiconductor (MOS) transistor. Using a MOS transistor implemented as a switch, however, introduces various errors in the voltage at the switched capacitor filter.

One source of error is known as charge injection. Typically, when the MOS transistor opens (i.e., as the gate voltage falls below the threshold voltage, and is now off), there is a transfer of charge through the source and drain terminals of the MOS transistor. The transfer of charge causes a leakage of charge (i.e., an injection of charge) from the MOS transistor to the capacitor, which in turn introduces an error in the voltage stored in the capacitor. Clock feed through and noise are other sources of error. As circuits have become more sophisticated and accuracy requirements have increased, errors due to charge injection and clock feed through have become critical in the proper operation of SCFs.

One common technique of reducing these errors includes using a charge cancellation circuit. FIG. 1 illustrates a charge cancellation circuit 100, which is typically used for reducing errors introduced because of charge injection effects. The charge cancellation circuit 100 comprises n-channel MOS (NMOS) transistors 106, 108, and 110, p-channel MOS (PMOS) transistor 114, 116, and 118, a clock input signal 102, an inverter 104, and output signals 112 and 120. Transistors 108 and 116 are coupled in parallel such that the source portion of transistor 108 is coupled to the drain portion of the transistor 116 and the drain portion of transistor 108 is connected to the source portion of transistor 116. When clock input signal 102 is high, transistor 116 is switched off and transistor 108 is switched off. Alternatively, when clock input signal 102 is low, transistor 116 is switched on and transistor 108 is switched on. Whenever clock input signal 102 toggles from high to low or from high to low, charges in the channel portion of transistor 108 and in the channel portion of transistor 116 dissipate (thereby possibly leading to charge injection errors). But, because the charges are opposite (i.e., majority carriers on transistor 108 are electrons and majority carriers on transistor 116 are holes), the charges cancel each cancel each other as they dissipate.

The charge cancellation technique described in FIG. 1 requires the clock input signal 102 to have a high amplitude. A clock signal having a high amplitude can interfere with the operation of sensitive circuitry, which typically operate on voltages that are a few milli-volts.

### SUMMARY

A system and method of generating a pair of synchronized signals is disclosed. As an example, the system may be a biased clock generator. The biased clock generator includes a first device connected between a first output voltage and an input reference voltage, the first device generating a first output clock signal, a second device connected in series with the first device, the second device connected between the input reference voltage and a second output voltage, the second device generating a second output clock signal. The biased clock generator further includes a first switching circuit connected in parallel with the first device, the first switching circuit operable to toggle the first device on and off; and a second switching circuit connected in parallel with the second device, the second switching circuit operable to toggle the second device on and off.

The first output clock signal oscillates between the input reference voltage and the first output voltage and the second output clock signal oscillates between the second output voltage and the input reference voltage. In this embodiment, the first output clock signal is one threshold voltage above the input reference voltage and the second output clock signal is one threshold voltage below the input reference voltage. Further, the input reference voltage is greater than zero volts. The input reference voltage is approximately one-half (½) of a rail voltage. Approximately is used because it may be difficult to set the input reference voltage at exactly one-half of the rail voltage. In one embodiment, the rail voltage is the input supply voltage (Vdd) of the biased clock generator. The input supply voltage Vdd supplies power to the biased clock generator.

In a preferred embodiment, the first device is a first NMOS transistor and the second device is a first PMOS transistor. The first NMOS transistor and the first PMOS transistor are coupled together such that a drain terminal of the first NMOS transistor is coupled to a first current source, a source terminal of the first NMOS transistor is coupled to the input reference voltage, and a gate of the first NMOS transistor is connected to the drain terminal of the first NMOS transistor. Further, a drain terminal of the first PMOS transistor is coupled to a second current source, a source terminal of the first PMOS transistor is coupled to the input reference voltage, and a gate of the first PMOS transistor is connected to the drain terminal of the first PMOS transistor.

In a preferred embodiment, the first switching circuit operates to connect the first current source to the first device for a first period of time and disconnect the first current source from the first device for a second period of time, wherein the first and second periods of time are substantially equal. In the same way, the second switching circuit operates to connect the second current source to the second device for the first period of time and disconnect the second current source from the second device for the second period of time. In the same or in another embodiment, the first switching circuit and the second switching operate in unison.

The first switching circuit preferably comprises a second NMOS transistor connected in parallel to a second PMOS transistor such that a source terminal of the second PMOS transistor is coupled to (i) a drain terminal of the second NMOS transistor and (ii) the drain terminal of the first NMOS transistor and a drain terminal of the second PMOS transistor is coupled to (i) a source terminal of the NMOS transistor and (ii) a source terminal of the NMOS transistor. Further, a gate terminal of the second NMOS transistor is coupled to a first inverter and a gate terminal of the second PMOS transistor is coupled a second inverter.

The second switching circuit comprises a third NMOS transistor connected in parallel to a third PMOS transistor such that a source terminal of the third PMOS transistor is coupled to (i) a drain terminal of the third NMOS transistor and (ii) the source terminal of the first PMOS transistor and a drain terminal of the third PMOS transistor is coupled to (i) a source terminal of the NMOS transistor and (ii) the drain terminal of the first PMOS transistor. Further, a gate terminal of the third PMOS transistor is coupled to the first inverter and a gate terminal of the third NMOS transistor is coupled to the second inverter.

The first and second inverters are each connected to a comparator. The comparator receives a first input clock signal and a second input clock signal, the comparator comparing the first input clock and the second clock signal. In a preferred embodiment, the comparator comprises a fourth NMOS transistor and a fifth NMOS transistor, the fourth and fifth NMOS transistors coupled to each other in series. In particular, a source terminal of the fourth NMOS transistor is coupled to a source terminal of the fifth NMOS transistor. Further, a gate terminal of the fourth NMOS transistor receives the first input clock signal and a gate terminal of the fifth NMOS transistor receives the second input clock signal.

In addition, an exemplary embodiment may take the form of a method. In particular, the method includes receiving, at a comparator, a pair of synchronized clock input signals, the pair comprising a first input clock signal and a second input clock signal; and determining, at the comparator, that the first input clock signal is greater than the second input clock signal. In response to this determination, the comparator sends a first signal that causes (i) a first device to generate a first output voltage that is one threshold voltage higher than an input reference voltage and (ii) a second device to generate a second output voltage that is one threshold voltage lower than the input reference voltage. In one embodiment, the first device is an NMOS transistor that is coupled to a first current source, and the second device is a PMOS transistor that is coupled to a second current source.

Further, the method includes determining, at the comparator, that the first input clock signal is less than the second input clock signal. In response to this determination, the comparator sends a signal that causes the first device to (i) generate a first output voltage that is substantially equal to the input reference voltage and a (ii) second output voltage that is substantially equal to the input reference voltage. In the same embodiment, a source terminal of the NMOS transistor is coupled to a drain terminal of the NMOS transistor, which in turn is coupled to the input reference voltage and a source terminal of the PMOS transistor is coupled to a drain terminal of the PMOS transistor, which in turn is coupled to the input reference voltage.

In the same embodiment or in another embodiment, the first NMOS transistor generates a first output clock signal that oscillates between the input reference voltage and the first output voltage and the first PMOS transistor generates a second output clock signal oscillating between the second output voltage and the input reference voltage.

### BRIEF DESCRIPTION OF THE FIGURES

Embodiments of the invention are described herein with reference to the drawings, in which:

FIG. 1 is a block diagram of a typical prior art charge cancellation circuit;

FIG. 2 is a block diagram depicting a switched capacitor filter circuit, in accordance with exemplary embodiments;

FIG. 3A is a block diagram depicting components of a biased clock generator, in accordance with exemplary embodiments;

FIG. 3B is another block diagram depicting components of a biased clock generator of an alternative embodiment;

FIG. 4 is a block diagram of a more detailed view of the components of biased clock generator 206 illustrated in FIG. 3A, in accordance with exemplary embodiments;

FIG. 5 is a block diagram of a switched capacitor integrator, in accordance with exemplary embodiments;

FIG. 6A is a graph illustrating output voltage versus time for the switched capacitor integrator illustrated in FIG. 5 when the biased clock generator is used;

FIG. 6B is a graph illustrating output voltage versus time for the switched capacitor integrator illustrated in FIG. 5 when the biased clock generator is not used; and

FIG. 7 is a flowchart of a method, in accordance with exemplary embodiments.

### DETAILED DESCRIPTION

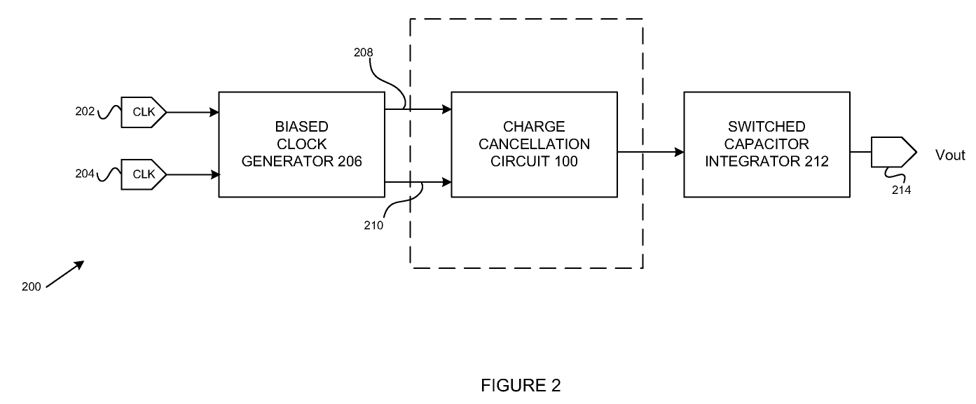

FIG. 2 is a simplified block diagram depicting an exemplary SCF circuit 200 that may be used in accordance with exemplary embodiments. As illustrated, SCF circuit 200 includes clock input signals 202 and 204, a biased clock generator 206, a charge cancellation circuit 100, a switched capacitor integrator 212, and an output 214.

It should be understood that the arrangements described herein are for purposes of example only. For example, charge cancellation circuit 100 in FIG. 2 may be omitted and clock signals 208 and 210 from biased clock generator 206 may be input directly to switched capacitor integrator 212 directly. As such, those skilled in the art will appreciate that other arrangements and other elements (e.g. machines, interfaces, functions, orders, and groupings of functions, etc.) can be used instead. Further, many of the elements described herein may be functional entities that may be implemented as discrete or distributed components or in conjunction with other components, in any suitable combination or location.

Further, it should be understood that the biased clock generator 206 does not necessarily have to be connected to switched capacitor integrator 212. Although the remainder of this application is directed to biased clock generator 206 being used in conjunction with switched capacitor integrator 212, it should be understood that biased clock generator 206 may be coupled to circuits other than switched capacitor integrator 212. For instance, biased clock generator 206 may be used with a basic switch that uses a sensitive signal.

In normal operation, biased clock generator 206 receives input clock signals 202 and 204. In one embodiment, input clock signals 202 and 204 are differential clock signals, such that clock input signal 204 is an inverted signal of clock signal 202. As one example, differential clock signal 202 and 204 may come from another biased clock generator. Biased clock generator 206 receives differential input clock signals 202 and 204 and generates differential output clock signals 208 and 210. Differential clock output signals 208 and 210 have characteristics that are optimized for the operation of the switched capacitor integrator 212. For instance, in one embodiment, biased clock generator 206 uses clock input signals 202 and 204 to generate differential clock signals 208 and 210 that are centered around a reference voltage. In this regard, clock signal 208 may be one threshold voltage higher than the reference voltage and clock signal 210 may be one threshold voltage below the reference voltage. The reference voltage may be set around the common mode voltage of the switched capacitor integrator 212. Typically, the common mode voltage is set to half of the supply voltage of the switched capacitor integrator 212.

In the same embodiment or in another embodiment, biased clock generator 206 generates differential clock signals 208 and 210 that have amplitudes optimized for the operation of the switched capacitor integrator 212. The amplitude of the differential clock signals 208 and 210 may have a lower amplitude than the differential input clock signals 202 and 204, but the amplitude of the differential output clock signals 208 and 210 may be high enough amplitude to drive switched capacitor integrator 212. Biasing the output clock signals 208 and 210 around a reference voltage and lowering the amplitude of each of the clock signals 208 and 210 reduces errors that may occur because of charge injection and clock feed through. Further, in the same embodiment or in another embodiment, clock signals 208 and 210 have the same phase and frequency as clock input signals 202 and 204.

When biased clock generator 206 receives the clock input signals 202 and 204, biased clock generator 206 compares the two clock signals. When clock signal 202 is greater than clock signal 204, biased clock generator 206 generates clocks clock signals 208 and 210 that are at the reference voltage (i.e., the common mode voltage of the switched capacitor integrator 212). And when clock signal 202 is less than clock signal 204, biased clock generator 206 generates differential clock signals 208 and 210 that are around one threshold voltage around the reference voltage. In this scenario, clock output signal 208 is one threshold voltage above the reference voltage and clock output signal 210 is one threshold voltage below the reference voltage.

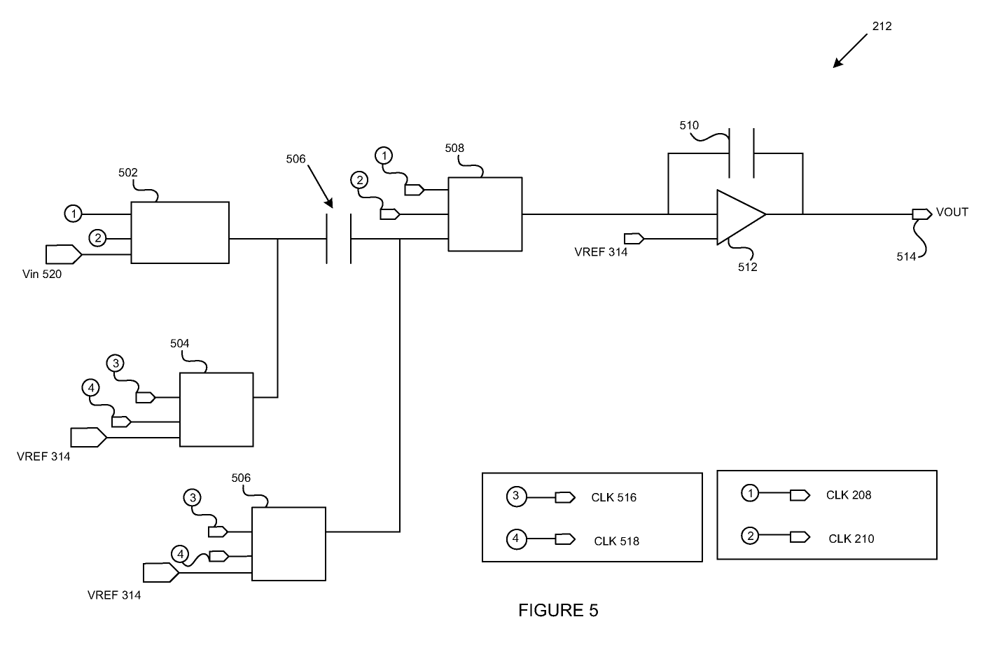

Switched capacitor integrator 212 is discussed more fully in connection with FIG. 5. In general, switched capacitor integrator 212 operates to eliminate noise caused by switching of an input signal. As shown in FIG. 2, switched capacitor integrator 212 is coupled to charge cancellation circuit 100 and generates an output voltage 214. Because biased clock generator 202 drives switched capacitor integrator 212 with clock signals 208 and 210 that are optimized for the operation of the switched capacitor integrator 210, output voltage 214 is characterized by fewer errors. Output voltage 214 may be a sine wave having a low frequency.

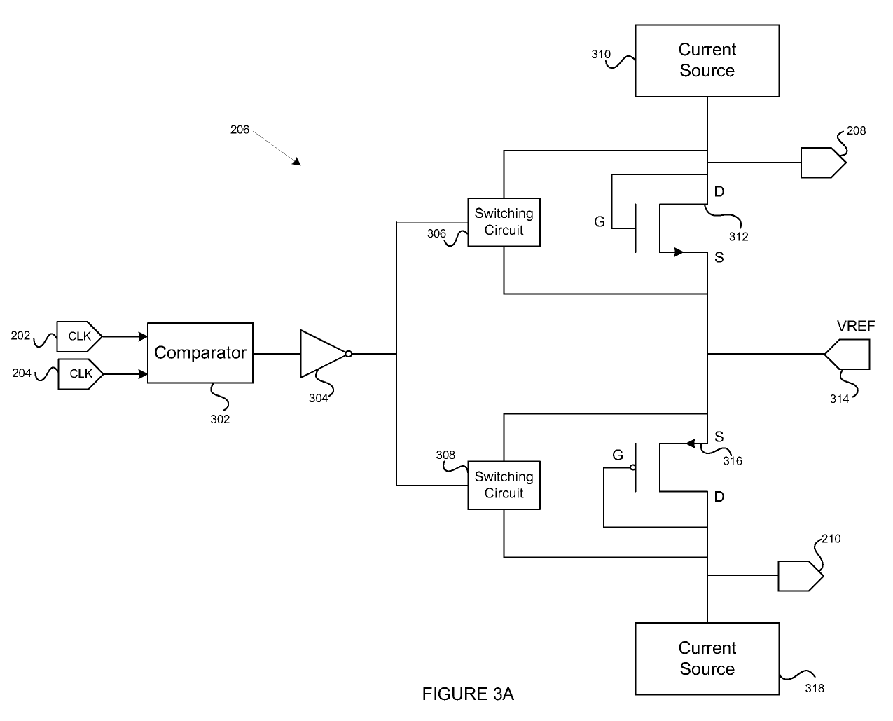

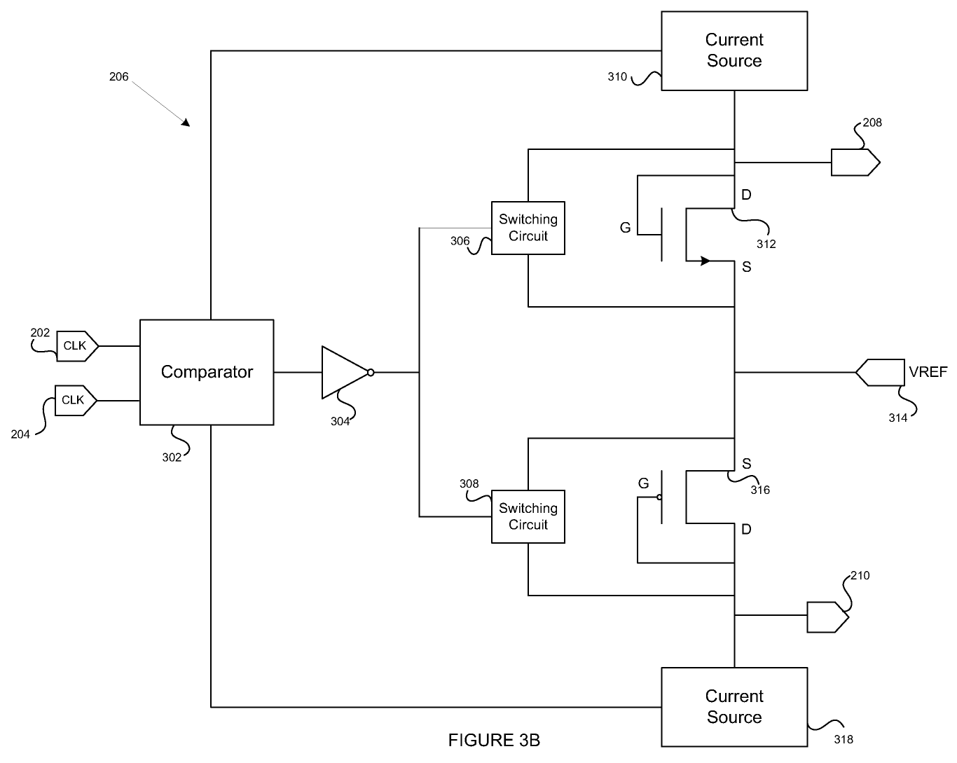

FIG. 3A is a simplified block diagram of biased clock generator 206, which may be used in accordance with exemplary embodiments. In particular, FIG. 3A depicts input clock signals 202 and 204, an input reference voltage 314, a comparator 302, an inverter 304, switching circuits 306 and 308, current sources 310 and 318, an NMOS transistor 312, a PMOS transistor 316, and output clock signals 208 and 210.

As shown in FIG. 3A, input reference voltage 314 is connected to the source terminal of the NMOS transistor 312 and the source terminal of the PMOS transistor 316. Input reference voltage 314 is set as mid-rail voltage, which is the power rail voltage divided by two (V_{DD}/2). In one aspect, the input reference voltage 314 may be generated by a reference voltage generator (not shown).

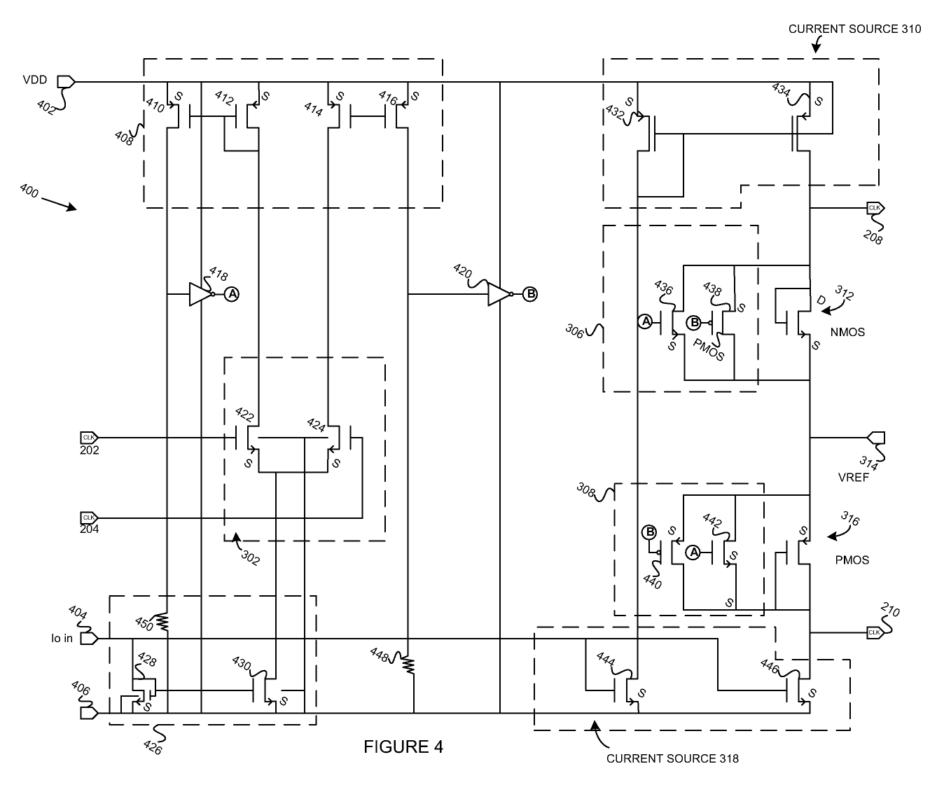

Switching circuit 306 is discussed more fully in connection with FIG. 4, but in general, switching circuit 306 selectively couples current source 310 to the drain terminal of the NMOS transistor 312. As an example, switching circuit 306 will open and close, thereby toggling NMOS transistor 312 on an off. When switching circuit 306 is open, current source 310 is coupled to the drain terminal of the NMOS transistor 312, which in turn is connected to the gate terminal of NMOS transistor 312. In effect, current source 310 is coupled to the gate of NMOS transistor 312, which causes the NMOS transistor 312 to be on (since the gate voltage is now greater than the threshold voltage of the NMOS transistor 312). In this condition, when NMOS transistor 312 is on, output clock signal 208 is one threshold voltage above the input reference voltage 314.

Alternatively, when switching circuit 306 is closed, current source 310 is now coupled to the source terminal of the NMOS transistor 312. This condition effectively short-circuits the NMOS transistor 312 (since the drain terminal of NMOS transistor 312 is connected to the source terminal of the NMOS transistor 312), causing the output clock signal 208 to be at the same potential as the reference voltage 314. In this condition, when NMOS transistor 312 is off, output clock signal 208 is substantially equal to the input reference voltage 314.

Switching circuit 308 is discussed more fully in connection with FIG. 4, but in general, switching circuit 308 selectively couples current source 318 to the drain terminal of the PMOS transistor 316. As an example, switching circuit 308 will open and close, thereby toggling NMOS transistor 316 on an off. When switching circuit 308 is open, current source 318 is coupled to the drain terminal of the PMOS transistor 316, which in turn is connected to the gate terminal of PMOS transistor 316. In effect, current source 318 is coupled to the gate of PMOS transistor 318, which causes the PMOS transistor 318 to be on (since the gate voltage is now greater than the threshold voltage of the PMOS transistor 316). In this condition, when PMOS transistor 316 is on, output clock signal 210 is one threshold voltage below the input reference voltage 314.

Alternatively, when switching circuit 308 is closed, current source 318 is now coupled to the source terminal of the PMOS transistor 316. This condition effectively short-circuits the PMOS transistor 316 (since the drain terminal of PMOS transistor 316 is connected to the source terminal of the PMOS transistor 316), causing the output clock signal 210 to be at the same potential as the reference voltage 314. In this condition, when PMOS transistor 312 is off, output clock signal 210 is substantially equal to the input reference voltage 314.

Comparator 302 is discussed more fully in connection with FIG. 4, but in general comparator 302 may be implemented as a differential transistor pair. Comparator 302 continuously compares input clock signals 202 and 204. When clock signal 202 is greater than clock signal 204, differential amplifier 302 generates a high signal (i.e., “1”). Inverter 304 then inverts the high signal, which forces switching circuits 306 and 308 to open. In such a condition, current source 310 to be coupled to the drain terminal of the NMOS transistor 312 and current source 318 to be coupled to the source terminal of the PMOS transistor 316.

Alternatively, when input clock signal 202 is less than input clock signal 204, differential amplifier 302 generates a low signal (i.e., “0”). Inverter 304 inverts the low signal into a high signal, which forces switching circuits 306 and 308 to close. In such a condition, the drain terminal and the source terminal of the NMOS transistor 312 are shorted; source terminal and the drain terminal of PMOS transistor 316 are shorted. In such a condition, output clock signals 208 and 210 are at the same potential as the input reference voltage 314. In a preferred embodiment, switching circuits 306 and 308 are synchronized to operate in unison such that whenever switching circuit 306 is open, switching circuit 308 is open, and when switching circuit 306 is closed, switching circuit 308 is closed. By synchronizing switching circuits 306 and 308 to operate in unison, biased clock generator 206 generates a synchronized pair of clock signals 208 and 210, which track each other in phase and frequency. In the same embodiment, switching circuit 306 couples current source 310 to NMOS transistor 312 for a first period of time and disconnects the current source 310 from the NMOS transistor 312 for a second period of time, wherein the first and second periods of time are substantially equal. Further, in the same embodiment or in another embodiment, when switching circuit 308 and 306 operate in unison, switching circuits 308 couples and disconnects PMOS transistor 316 for the same period of time that switching circuit 306 couples and disconnects NMOS transistor 312 from current source 310.

In this way, comparator 302 uses clock signals 202 and 204 to drive NMOS transistor 312 and PMOS transistor 316 to generate clock signals 208 and 210 that are centered around reference voltage 314. The comparator 302 controls switching circuits 306 and 308 so that the NMOS 312 (i.e., first device) and PMOS 316 (i.e., second device) are toggled on and off in unison. Table 1, below, summarizes the operation of biased clock generator 206.

TABLE 1

| CLK | SC 306 | NMOS | PMOS | | |
|---|---|---|---|---|---|
| Inputs | and 308 | 312 | 316 | CLK 208 | CLK 210 |
| 202 > 204 | OPEN | ON | ON | 1 THRSHLD | 1 THRSHLD < |
| | | | | >V_{REF} | V_{REF} |
| 202 < 204 | CLOSED | OFF | OFF | EQUAL TO | EQUAL TO |
| | | | | V_{REF} | V_{REF} |

FIG. 3B illustrates an alternative embodiment of biased clock generator 206, which may be used in accordance with exemplary embodiments. As shown in FIG. 3B, current sources 310 and 318 are coupled to the inverter 304. In the previous embodiment, illustrated in FIG. 3A, current sources 310 and 318 were always on. In FIG. 3B, current sources 310 and 318 are controlled such that current sources 310 and 318 turned on and off based on the input clock signals 202 and 204. In a preferred embodiment, current source 310 is turned turn on whenever differential amplifier 302 operates to open switching circuit 306, and current source 310 is turned off whenever differential amplifier 302 operates to close switching circuit 306.

And similarly, in the same embodiment, current source 318 is turned on whenever differential amplifier 302 operates to open switching circuit 308 and current source 318 is turned off whenever differential amplifier 302 operates to close switching circuit 308. Table 2, below, summarizes the operation of biased clock generator 206.

TABLE 2

| | SC 306 & | SRC 310 & | NMOS | PMOS | | |
|---|---|---|---|---|---|---|
| | 308 | 318 | 312 | 316 | CLK 208 | CLK 210 |
| 202 > 204 | OPEN | ON | ON | ON | 1 THRSHLD | 1 THRSHLD |
| | | | | | >V_{REF} | <V_{REF} |
| 202 < 204 | CLOSED | OFF | OFF | OFF | EQUAL TO | EQUAL TO |
| | | | | | V_{REF} | V_{REF} |

FIG. 4 illustrates a more detailed view of biased clock generator 206. In FIG. 4, like elements of biased clock generator 206 in circuit 300 are referenced with the same reference number. Specifically, circuit 400 of biased clock generator 206 includes clock signals 202 and 204, input reference voltage 314, and clock signals 208 and 210. While FIG. 4 illustrates particular implementations for the switching circuits 306, 308, comparator 302, current sources 310 and 318, it will be appreciated that these elements of the biased clock generator 206 may be implemented in any number of ways.

FIG. 4 illustrates the internal elements of switching circuits 306 and 308, current sources 310 and 318, and comparator 302. Further, FIG. 4 includes a power rail (Vdd) 402, a ground rail (Vss) 406, reference current (I_{O}) 404, and resistors 448 and 450. In one aspect, in its most basic form, reference current I_{O} 404 is generated (not shown) by placing a resistor between power rail (Vdd) and the transistor 428. I_{O} 404 feeds current to current mirrors 426, current source 310 and 318.

As shown in FIG. 4, comparator 302 includes a differential transistor pair. In particular, the pair includes a first n-type field effect transistor (FET) 422 and a second n-type FET 424. The first n-type FET 422 and the second n-type FET 424 are separately coupled in a parallel configuration. Specifically, respective drain terminals of the first n-type FET 422 and the second n-type FET 424 are coupled to circuit 408. As shown in FIG. 4, circuit 408 includes two current mirrors. Circuit 408 assists in generating signals A and B, which control switching circuits 306 and 308. Further, circuit 426 functions to bias comparator 302. Further, respective source terminals of the first n-type FET 422 and the second n-type FET 424 are coupled with each other and further coupled with circuit 426.

Current source 310, as shown in FIG. 4, is implemented as a constant current source. Current source 310 comprises a current mirror that includes a first n-type FET 432 and a second n-type FET 434. The first n-type FET 432 and the second n-type FET 434 are coupled in a stacked arrangement between the power rail (Vdd) 402 and NMOS transistor 312. Specifically, the source terminals of the first n-type FET 432 and of the second n-type FET 434 are coupled to the power rail 402 and the gates of the FET 432 and FET 434 are coupled with each other. Further, the drain terminal of FET 434 is coupled to the drain terminal of the NMOS transistor 312.

Current source 318 comprises a current mirror source that comprises a first n-type FET 444 and a second n-type FET 446. The first n-type FET 444 and the second n-type FET 446 are coupled in a stacked arrangement between the ground rail (Vss) 406 and PMOS transistor 316. Specifically, the source terminals of the first n-type FET 434 and of the second n-type FET 446 are coupled to the ground rail 406 and the gates of the FET 432 and FET 434 are coupled with each other. Further, the drain terminal of FET 436 is coupled to the drain terminal of the NMOS transistor 312.

It should be understood that each of current sources 310 and 318 may be implemented in any number of ways, such as a constant current source or a variable current source that is operated to provide a constant current (tail current) to the NMOS transistor 312 and PMOS transistor 316 respectively. Table 3, below, summarizes the operation of biased clock generator 206 illustrated in FIG. 4.

TABLE 3

| | | | NMOS | PMOS | | |
|---|---|---|---|---|---|---|
| | A | B | 312 | 318 | CLK 208 | CLK 210 |
| 202 > 204 | 0 | 1 | ON | ON | 1 THRSHLD> | 1 THRSHLD < |
| | | | | | V_{REF} | V_{REF} |
| 202 < 204 | 1 | 0 | OFF | OFF | EQUAL TO | EQUAL TO |
| | | | | | V_{REF} | V_{REF} |

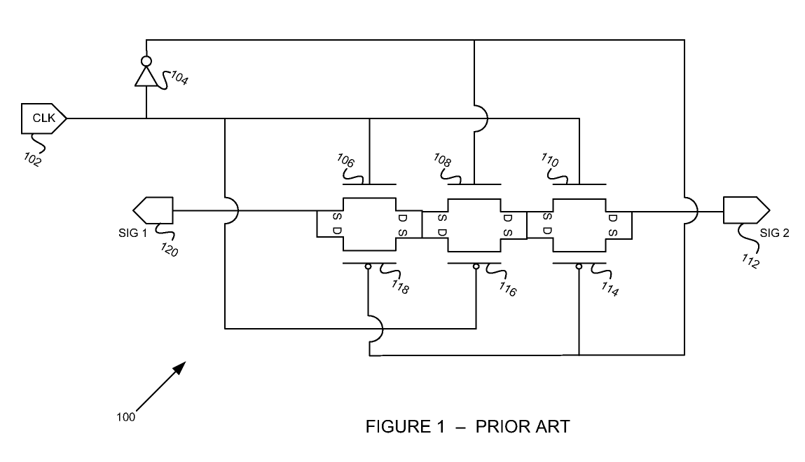

FIG. 5 is a block diagram of switched capacitor integrator 212. As shown in FIG. 5, switched capacitor integrator 212 includes components 502, 504, 506, and 508, a first capacitor 506, an operational amplifier 512, a second capacitor 510, an output voltage 514, an input voltage 520, clock signals 208, 210, 516, and 518. In one embodiment, clock signals 208 and 210 are generated from biased clock generator 206 and clock signals 516 and 518 are generated from a second biased clock generator (now shown), in which the biased clock generator 206 and the second biased clock generator (not shown) are non-overlapping clock generators. As shown in FIG. 5, switched capacitor integrator 212 receives output clock signals 208 and 210 from biased clock generator 206. Each of the components 502, 504, 506, and 508 is implemented as a switch illustrated in FIG. 1. As shown in FIG. 1, each of the components 502, 504, 506, and 508 has charge cancellation circuits.

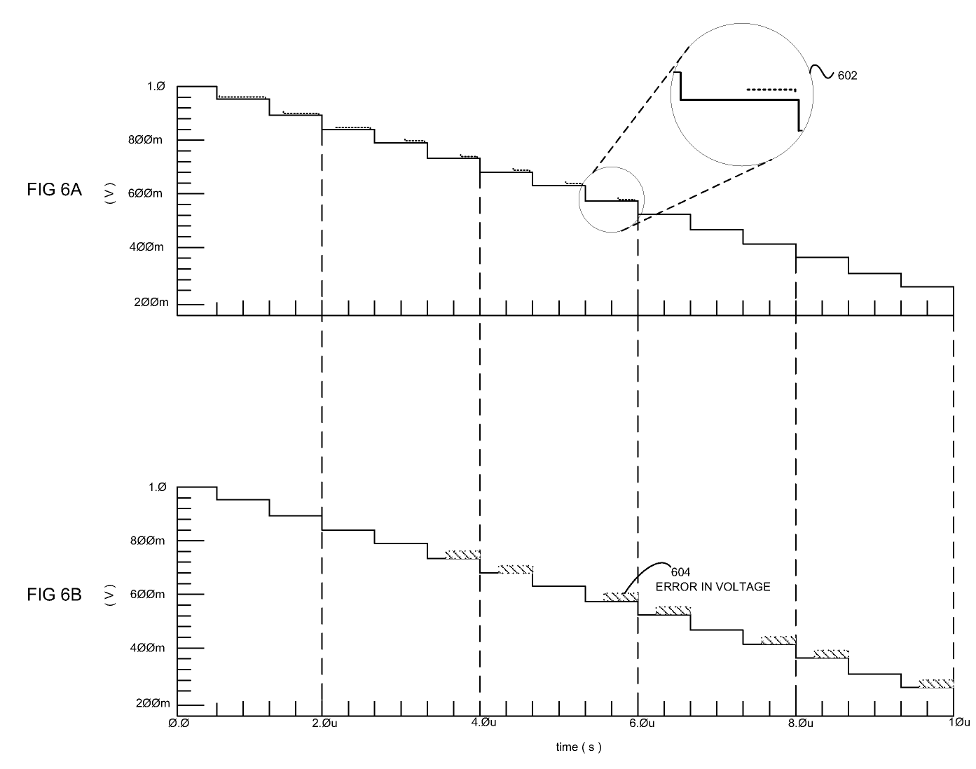

FIGS. 6A-B illustrate graphs of output voltage 214. In particular, FIG. 6A illustrates a graph of output voltage 214 when biased clock generator 206 is used with switched capacitor integrator 212. And FIG. 6B illustrates a graph of output voltage 214 when biased clock generator 206 is not used with switched capacitor integrator 212. It should be noted that FIGS. 6A and 6B are not drawn to scale.

FIG. 6A illustrates the voltage generated by switched capacitor 212 when biased clock generator 206 is used with switched capacitor integrator 212. Inset 602 magnifies a portion of the output voltage in FIG. 6A. The solid line in FIG. 6A indicates the ideal voltage and the dashed line in FIG. 6A indicates the measured voltage. In FIG. 6A, the solid line tracks the dashed line very closely, indicating that the errors (which may occur because of charge injection and clock feed through errors) have been minimized because the biased clock generator 206 is in use.

In FIG. 6B, the solid line (just like the solid line in FIG. 6A) indicates the ideal voltage that is supposed to be generated by switch capacitor integrator 212 in ideal situations. The dashed line in FIG. 6B indicates the actual voltage generated by the switched capacitor integrator 212 when biased clock generator 206 is not used. The solid line in FIG. 6B indicates the ideal voltage generated by the switched capacitor integrator 212 with no errors. The shaded area 604 indicates an error in voltage stored in the switched capacitor integrator 212. These errors may be because of charge injection and clock feed through errors. Comparing FIG. 6A with FIG. 6B, the shaded area 604 is larger than the area shown by inset 602. In this regard, biased clock generator 206 advantageously reduces errors. As one example, the biased clock generator 206 reduced errors because of charge injection and clock feed through.

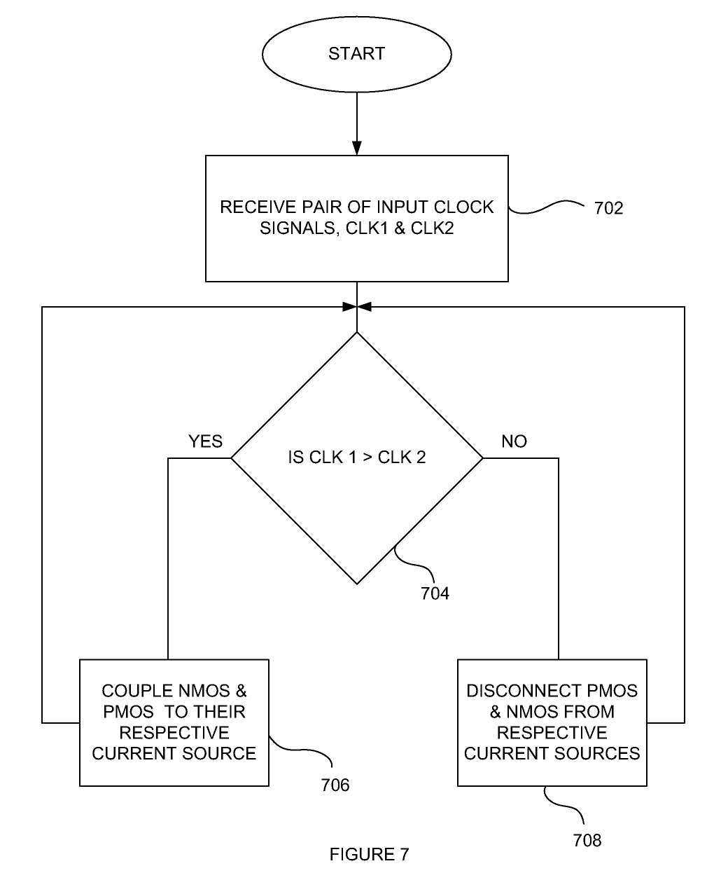

FIG. 7 is a flowchart depicting a method of generating a pair of synchronized clock output signals in accordance with an exemplary embodiment. As shown in FIG. 7, method 700 begins at block 702 when comparator 302 receives a differential pair of input clock signals. The pair of input clock signals may include a first input clock signal and a second input clock signal. The pair of input clock signals may oscillate between a high voltage of one volt and low voltage of zero volts such that when the first input clock signal is high, the second input clock signal is low and when the first input clock signal is low, the second input clock signal is high. Each of the first and second input clock signals oscillates from a low voltage of zero volts and a high voltage of 1 volt.

Next, block 704 includes making a determination of whether the first input clock signal is greater than the second input clock signal. As an example, comparator 302 may make this determination by comparing the amplitude of the first input clock signal 202 with the second input clock signal 204.

If the determination is that the amplitude of the first clock signal is greater than that of the second input clock signal, then, at block 706, NMOS 312 is coupled to current source 310 and PMOS 316 is coupled to current source 318. As an example, if comparator 302 determines that clock signal 202 is greater than clock signal 204, comparator 302 sends a signal to open each of the switching circuits 306 and 308. The signal may be a digital control signal. When switching circuits 306 and 308 have been opened, current source 310, in effect, is coupled to the drain terminal of the NMOS transistor 312 and current source 318 is coupled to the drain terminal of the PMOS transistor 316. This forces NMOS transistor 312 to be on and PMOS transistor 316 to be on. In this regard, NMOS transistor 312 generates an output clock signal 208 that has a voltage one threshold voltage higher than the input reference voltage 314 and PMOS transistor 316 generates an output clock signal 210 that has a voltage one threshold voltage below the input reference voltage. Input reference voltage 314 is approximately one-half (½) of the power rail voltage.

Alternatively, if the determination is that the first clock signal is less than the second input clock signal, then, at block 708, NMOS 312 is disconnected from current source 310 and PMOS 316 is disconnected from current source 318. As an example, if the comparator 302 determines that clock signal 202 is less than clock signal 304, comparator 302 sends a signal to close switching circuits 308 and 310. The signal may be a digital control signal. When switching circuits 306 and 308 have been closed, the drain terminal and the source terminal of the NMOS transistor 312 are coupled together, thereby short-circuiting NMOS transistor 312. In such a scenario, switching circuit 306 causes an output clock signal 208 to be generated that has a voltage potential substantially equal to the input reference voltage 314. In the same regard, the drain terminal and the source terminal of the PMOS transistor 316 are coupled together, thereby short-circuiting PMOS transistor 316. In such a scenario, switching circuit 308 causes an output clock signal 210 to be generated that has a voltage potential substantially equal to the input reference voltage.

While a number of aspects and embodiments have been discussed above, it will be appreciated that various modifications, permutations, additions and/or sub-combinations of these aspects and embodiments are possible. It is therefore intended that the following appended claims and claims hereafter introduced are interpreted to include all such modifications, permutations, additions and/or sub-combinations as are within their true spirit and scope.

1. A biased clock generator operable to generate a pair of synchronized output clock signals, the biased clock generator comprising:
a first device connected between a first output voltage and an input reference voltage, the first device generating a first output clock signal;
a second device connected in series with the first device, the second device connected between the input reference voltage and a second output voltage, the second device generating a second output clock signal;
a first switching circuit connected in parallel with the first device, the first switching circuit operable to toggle the first device on and off; and
a second switching circuit connected in parallel with the second device, the second switching circuit operable to toggle the second device on and off.

2. The biased clock generator of claim 1, wherein:
the first output clock signal oscillates between the input reference voltage and the first output voltage; and
the second output clock signal oscillates between the second output voltage and the input reference voltage.

3. The biased clock generator of claim 2, wherein:
the first output clock signal is one threshold voltage above the input reference voltage; and
the second output clock signal is one threshold voltage below the input reference voltage.

4. The biased clock generator claim 3, wherein:
the input reference voltage is greater than zero volts; and
the input reference voltage is approximately one-half (½) of an input rail voltage of the biased clock generator.

5. The biased clock generator of claim 1, wherein:
the first device is a first N-MOS transistor; and
the second device is a first P-MOS transistor.

6. The biased clock generator of claim 5,
wherein a drain terminal of the first NMOS transistor is coupled to a first current source, a source terminal of the first NMOS transistor is coupled to the input reference voltage, and a gate of the first NMOS transistor is connected to the drain terminal of the first NMOS transistor; and
wherein a drain terminal of the first PMOS transistor is coupled to a second current source, a source terminal of the first PMOS transistor is coupled to the input reference voltage, and a gate of the first PMOS transistor is connected to the drain terminal of the first PMOS transistor.

7. The biased clock generator of claim 6, wherein the first switching circuit operates to connect the first current source to the first device for a first period of time and disconnect the first current source from the first device for a second period of time, wherein the first and second periods of time are substantially equal.

8. The biased clock generator of claim 7, wherein the second switching circuit operates to connect the second current source to the second device for the first period of time and disconnect the second current source from the second device for the second period of time.

9. The biased clock generator of claim 6, wherein each of the first and second switching circuits is coupled to first and second inverters.

10. The biased clock generator of claim 9, wherein:
the first switching circuit and the second switching circuit are synchronized to operate in unison, in which the:
(a) the first switching circuit comprises a second NMOS transistor connected in parallel to a second PMOS transistor such that:
a source terminal of the second PMOS transistor is coupled to (i) a drain terminal of the second NMOS transistor and (ii) the drain terminal of the first NMOS transistor,
a drain terminal of the second PMOS transistor is coupled to (i) a source terminal of the second NMOS transistor and (ii) a source terminal of the first NMOS transistor; and
(b) the second switching circuit comprises a third NMOS transistor connected in parallel to a third PMOS transistor such that:
a source terminal of the third PMOS transistor is coupled to (i) a drain terminal of the third NMOS transistor and (ii) the source terminal of the first PMOS transistor,
a drain terminal of the third PMOS transistor is coupled to (i) a source terminal of the third NMOS transistor and (ii) the drain terminal of the first PMOS transistor.

11. The biased clock generator of claim 10, wherein a gate terminal of the second NMOS transistor is coupled to the first inverter and a gate terminal of the second PMOS transistor is coupled the second inverter.

12. The biased clock generator of claim 10, wherein a gate terminal of the third PMOS transistor is coupled to the first inverter and a gate terminal of the third NMOS transistor is coupled to the second inverter.

13. The biased clock generator of claim 9, wherein the first and second inverters are each connected to a comparator, the comparator receiving a first input clock signal and a second input clock signal, the comparator comparing the first input clock and the second clock signal.

14. The cock generator of claim 13, wherein the comparator comprises a fourth NMOS transistor and a fifth NMOS transistor, the fourth and fifth NMOS transistors coupled to each other in series such that a source terminal of the fourth NMOS transistor is coupled to a source terminal of the fifth NMOS transistor, and a gate terminal of the fourth NMOS transistor receives the first input clock signal and a gate terminal of the fifth NMOS transistor receives the second input clock signal.

15. A method of generating a pair of synchronized clock signals, the method comprising:
receiving, at a comparator, a pair of synchronized clock input signals, the pair comprising a first input clock signal and a second input clock signal; and
determining, at the comparator, that the first input clock signal is greater than the second input clock signal, and in response, sending a signal that causes (i) a first device to generate a first output voltage that is one threshold voltage higher than an input reference voltage and (ii) a second device to generate a second output voltage that is one threshold voltage lower than the input reference voltage.

16. The method of claim 15, further comprising:
determining, at the comparator, that the first input clock signal is less than the second input clock signal, and in response, sending a signal that causes the first device to (i) generate a first output voltage that is substantially equal to the input reference voltage and a (ii) second output voltage that is substantially equal to the input reference voltage.

17. The method of claim 16, wherein sending a signal that causes (i) the first device to generate a first output voltage that is one threshold voltage higher than an input reference voltage and (ii) the second device to generate a second output voltage that is one threshold voltage lower than the input reference voltage comprises coupling (i) a first NMOS transistor to a first current source and (ii) a first PMOS transistor to a second current source, wherein the first NMOS transistor generates the first output voltage and the first PMOS transistor generates the second output voltage.

18. The method of claim 17, wherein sending a signal that causes the first device to (i) generate a first output voltage that is substantially equal to the input reference voltage and a (ii) second output voltage that is substantially equal to the input reference voltage, comprises coupling (i) a source terminal of the NMOS transistor to the input reference voltage and (ii) a source terminal of the PMOS transistor to the input reference voltage.

19. The method of claim 18, wherein:
the first NMOS transistor generates a first output clock signal oscillating between the input reference voltage and the first output voltage; and
the first PMOS transistor generates a second output clock signal oscillating between the second output voltage and the input reference voltage.

20. The method of claim 19, wherein first input clock signal has a higher amplitude than that of the first output clock signal and the second input clock signal has a higher amplitude than that of the second output clock signal.
